(19) United States
(12) Patent Application Publication
(10) Pub. No.: US 2003/0042998 A1
(43) Pub. Date: Mar. 6, 2003

(54) Leaky surface acoustic wave resonators

(76) Inventor: Peter J. Edmonson, Hamilton (CA)

Correspondence Address: GOLING LAFLEUR HENDERSON LLP, PO Box 1045 LCD1, Suite 560, 120 King Street West, Hamilton, ON, L8N 3R4, CA

(21) Appl. No.: 10/226,331

(22) Filed: Aug. 23, 2002

Related U.S. Application Data
(60) Provisional application No. 60/314,298, filed on Aug. 24, 2001.

(51) Int. Cl. H03H 9/64

(52) U.S. Cl. 333/195; 310/313 D

(57) ABSTRACT

A leaky surface acoustic wave resonator includes reflectors each having metal fingers on the piezoelectric substrate. The metal fingers have a ration of finger width to finger width plus the width of the space therebetween of from 0.75 to 1.0.

### RELATED APPLICATION

This application claims priority from U.S. Provisional Patent Application No. 60/314298 filed Aug. 24, 2001.

### FIELD OF INVENTION

This invention relates to leaky surface acoustic wave (LSAW) resonators. Such resonators include interdigital transducers (IDTs) and reflectors each having metal fingers on a piezoelectric substrate.

### BACKGROUND OF INVENTION

It is expected that the use of LSAW resonators in the frequency range of 2-5 GHz in products such as RF tags, cell phones and wireless local area networks (WLANs), will increase in the near future. However, a major manufacturing problem exists in achieving consistency in the very small line widths and manufacturing yields to enable resonators operable satisfactorily at these high frequencies to be produced.

One solution is to construct the IDTs for a lower frequency and implement their harmonic behaviour to achieve the desired higher response. Another solution is to construct the finger widths of the reflectors twice the width of the IDTs used. This method unfortunately results in reduced reflectivity. Generally, there are many more reflector fingers than IDT fingers in a resonator, resulting in a larger device to accommodate the many wider reflector fingers.

It is therefore an object of the invention to provide LSAW resonators which operate satisfactorily at the higher frequencies mentioned and which are not undesirably large.

### SUMMARY OF INVENTION

Prior art reflectors commonly used at the present time usually have a metallization ratio of 0.5, the metallization ratio being the ratio of finger width to finger width plus width of the space therebetween. According to the present invention, the individual fingers of prior art reflectors with a metallization m=0.5 are replaced by wider fingers of sub-harmonic frequency geometries with metallization ratios of at least about 0.75 to the limit of m=1.0. This reduces the precise line width to the area of fewer fingers in the region of the IDTs and shortens the overall structure of the device as the total number of effective wider sub-harmonic reflectors can be reduced. At the limit of m=1.0, the wider sub-harmonic fingers become a solid plate reflector. Thus, the invention solves both the problem of reduced reflectivity and the problem of total length of the reflectors gratings.

Resonators with such wider sub-harmonic reflector fingers with metallization ratios of at least about 0.75 and, at the limit solid reflectors, in accordance with the invention on each side of an IDT are bound not so much as or not at all by reflector line width constraints and yield problems. They consequently have higher reflectivity characteristics than individual sets of reflector fingers with m=0.5, resulting in a shorter device and hence a small overall package size.

Most of the front-end radio frequency (RF) resonator type filters in modern wireless communication devices, such as cell phones, two-way pagers, RF tags and WLANs, utilize some form of LSAW structures with IDTs and pairs of reflection gratings. An LSAW resonator in accordance with the present invention can readily be incorporated into such devices for improved performance.

### DESCRIPTION OF THE DRAWINGS

Embodiments of the invention will now be described, by way of example, with reference to the accompanying drawings, of which:

FIG. 1 is a graph illustrating reflectivity versus film thickness ratio in known resonators,

FIG. 2 is a diagrammatic view of a resonator in accordance with the prior art,

FIG. 3 is a similar view but showing a resonator in accordance with one embodiment of the present invention,

FIG. 4 is a similar view but showing a resonator in accordance with another embodiment of the invention,

FIG. 5 shows diagrammatic views of metallized grating reflectors with different metallization ratios,

FIG. 6 is a graph showing reflectivity versus film thickness ratio for various metallization ratios, and

FIG. 7 is a graph showing reflectivity versus film thickness ratio for higher metallization ratios.

### DESCRIPTION OF PREFERRED EMBODIMENTS

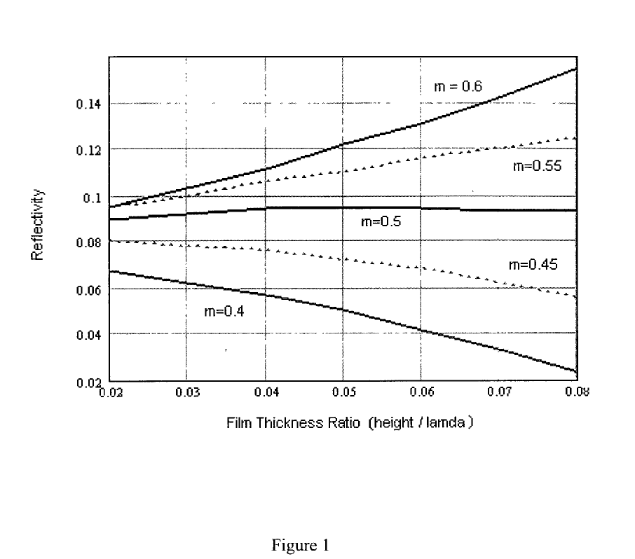

Referring to the drawings, the graph shown in FIG. 1 is taken from a paper by Lehtonen et al, “Second Harmonic Reflectors,” Proc. 2000 IEEE Ultrasonics Symp.

The graph shows that second harmonic reflectivity (SHR) increases with increasing film thickness ratio h/λ for a metallization m>0.5 and decreases for a metallization m<0.5. In FIG. 1, the upper trace is for m=0.6 and lower traces reduce in steps of 0.05 to the lowest trace of m=0.4.

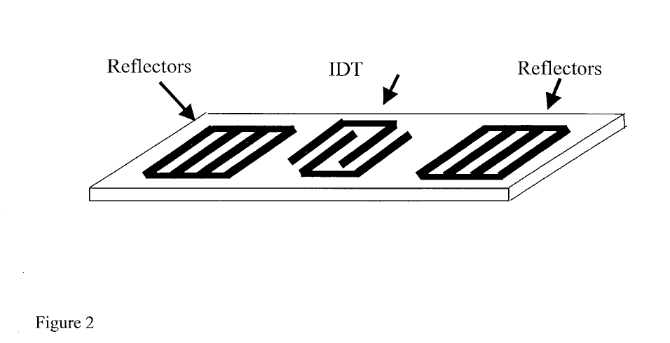

A prior art resonator implementing equal width fingers of m=0.5 in both the IDTs and reflector gratings is shown in FIG. 2. Normally the finger width (mark) is one-quarter wavelength in width and is equal to the space adjacent to it (space). The metallization ratio is the ratio of the solid finger (mark) with the total distance (mark+space). If an equal quarter wavelength mark and space are implemented, the metallization ratio is then m=0.5.

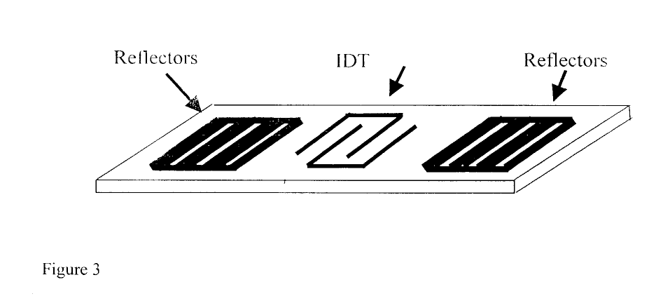

FIG. 3 shows a leaky surface acoustic wave resonator incorporating sub-harmonic reflectors with a metallization ratio m=0.75, in accordance with the present invention.

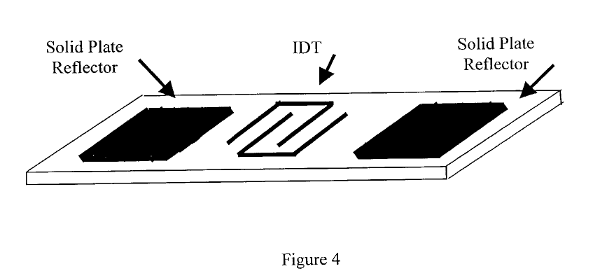

FIG. 4 shows a leaky surface acoustic wave resonator incorporating solid plate reflectors in accordance with the present invention. Thus, the end grating reflectors have been replaced by solid conducting plates, with m therefore being 1.

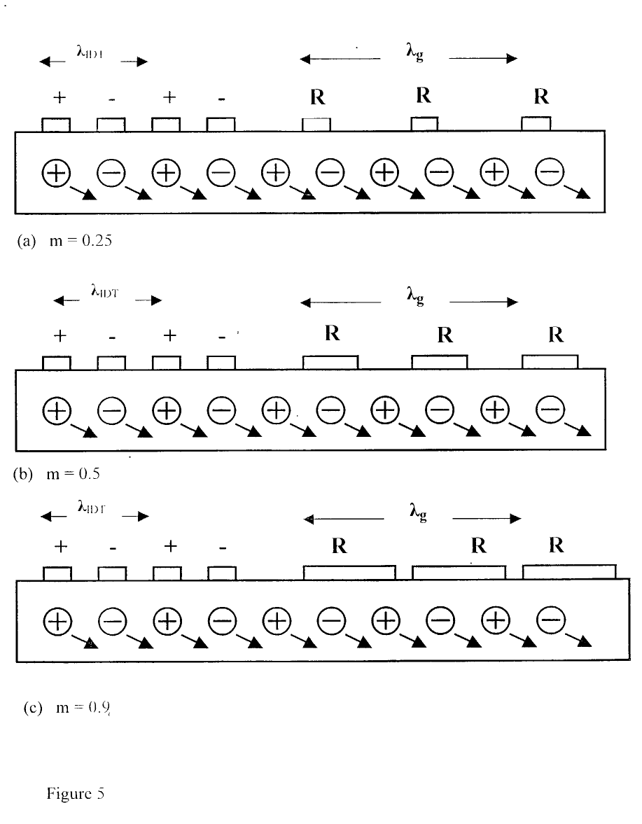

It has been realized that the solution to the phenomenon described with reference to FIG. 1 may be attributed to the LSAW wave motion and the shorting characteristics of the regions just under the metallized reflectors. The interesting parameter is the metallization ratio m of the reflectors in that, for values of m<0.5, the reflectivity shows behaviour similar to that of 128° LiNbO₃, see Lehtonen, et al, “Second Harmonic Reflectors,” Proc. 2000 IEEE Ultrasonics Symp. For values of m>0.5 though, there is an increase in reflectivity as the film thickness ratio increases. An examination of the LSAW wave motion under the reflectors as depicted in FIG. 5 illustrates how this motion is relative to the metallized regions ranging from m=0.25 to m=0.9. The reflectors are constructed such that their geometries are at a frequency one-half of the IDT frequency (λ_{g}=2λ_{IDT}).

For metallization values of m<0.5, the LSAW motion is only under or partially under a single metallized reflector. When m>0.5, the metallized reflector finger begins to encompass both the positive and negative polarized wave motions \mathring{+} and \mathring{−}, effectively shorting the two oppositely polarized waves together. This shorting phenomenon will effectively increase and hence also effectively increase the reflectivity as the metallization ratio increases from at least about m=0.75 to the limit of m=1.0.

Inventor Edmonson has made a modification to the mutual coupling coefficient, κ₁₂ (kappa), in that a metallization variable (m) is included, as shown below.

$${kappa}_{{m}_{f , m}} \text{:} = [ 0.0083 {ⅇ}^{\frac{m}{20}} + 0.48 \frac{{f}^{\frac{3}{2}}}{112} \cdot ( \frac{m}{20} - 0.496 ) ] \cdot {kmid}_{o}$$

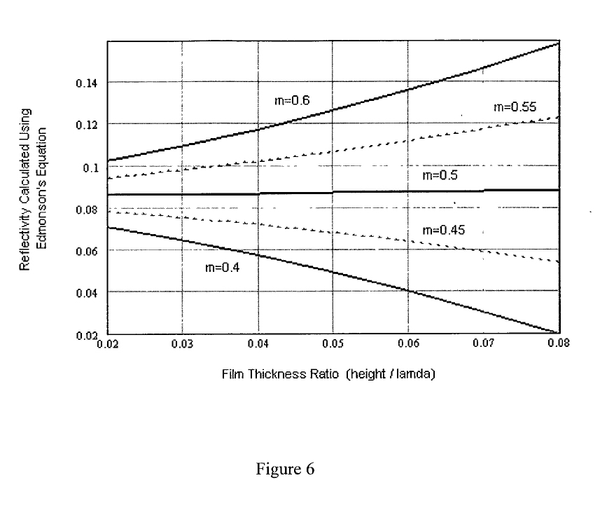

The above equation was then used to plot the reflectivities of FIG. 1, as shown in FIG. 6. An interesting feature of this equation is that a much higher reflectivity is produced when the reflector metallization ratio is at least about m=0.75 to the limit m=1.0. This higher reflectivity is a result of increased shorting under the metallized regions between the two leaky wave protorizations.

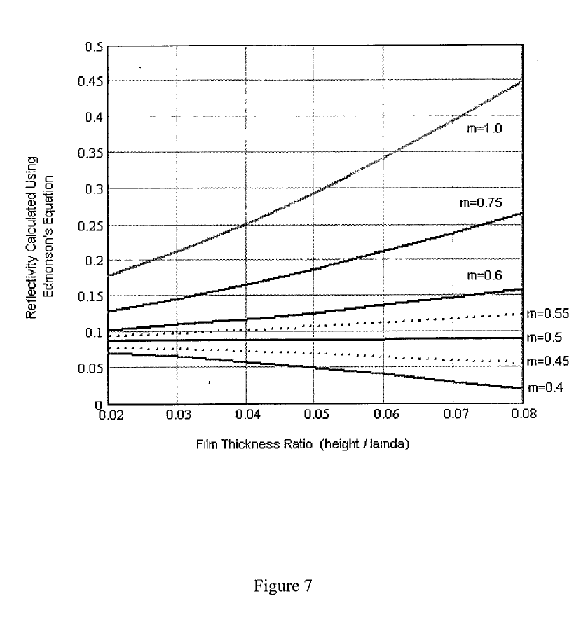

Wider sub-harmonic reflectors with m at least throughout 0.75 and, in the limit solid plate reflectors with m=1.0, in accordance with the invention will have a higher reflectivity. FIG. 7 illustrates theoretically the reflectivity for metallization ratios from m=1.0 (upper trace) and m=0.75 (second trace from the top), with the other traces representing the values of FIG. 6.

Other embodiments of the invention will now be readily apparent to a person skilled in the art, the scope of the invention being defined in the appended claims.

1. A leaky surface acoustic wave resonator including reflectors each having metal fingers on a piezoelectric substrate, and
said metal fingers having a ratio of finger width to finger width plus the width of the space therebetween of from about 0.75 to 1.0.

2. A resonator according to claim 1 wherein said ratio is 1.0, with said fingers of each reflector merging to form a plate.
